(19) United States
(12) Patent Application Publication
(10) Pub. No.: US 2008/0050905 A1
(43) Pub. Date: Feb. 28, 2008

(54) METHOD OF MANUFACTURING SEMICONDUCTOR DEVICE

(75) Inventors: Masayuki UCHIDA, Kawasaki-shi (JP); Kazuhito Higuchi, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/753,989

(22) Filed: May 25, 2007

(30) Foreign Application Priority Data
May 29, 2006 (JP) P2006-147711

(51) Int. Cl. H01L 21/44

(52) U.S. Cl. 438/614; 257/E21.476

(57) ABSTRACT

A semiconductor device is fabricated by making first and second UBM films on an external terminal, the first under bump metal film having no wettability to a bump electrode and the second UBM film having wettability to the bump electrode; placing the bump electrode on the second UBM film; patterning and side-etching the second UBM film using the bump electrode as a mask; filling a resist in a space defined by the side-etched part of the second UBM film; and patterning the first UBM film using the bump electrode and the resist as a mask.

### CROSS REFERENCE TO RELATED APPLICATION

This application is based upon and claims the benefit of priority from the prior Japanese Patent Application No. 2006-147711 filed on May 29, 2006, the entire contents of which are incorporated herein by reference.

### BACKGROUND OF THE INVENTION

1. Field of the Invention

This invention relates to a method of manufacturing a semiconductor device, and more particularly to a method of manufacturing a semiconductor device in which a bump electrode is placed on an external terminal of a substrate via an under-bump metal film.

2. Description of the Related Art

The flip-chip method is applied to mounting a semiconductor device. With the flip-chip method, an external terminal (a bonding pad) of a semiconductor chip and an external terminal of a wiring substrate are electrically connected by a bump electrode, and are mechanically joined. Further, the flip-chip method is applicable to mounting semiconductor chips, and wiring substrates. This method is effective in reducing a mounting space and compacting the semiconductor device, because wires are not laid in a complicated manner which is inevitable in the bonding wire method.

The bump electrode is usually made of solder, which is prepared by the plating, printing or deposition process. First of all, an under-bump metal film (hereinafter called the “UBM film”) is made on the external terminal of the semiconductor chip, so that the bump electrode is made on the UBM film.

In the semiconductor device adopting the flip-chip method, stress concentration is caused at the bump electrode or at a joint between the bump electrode and the external terminal because of not only a difference of thermal expansion coefficients of the semiconductor chip, wiring substrate and bump electrode but also temperature cycling resulting from circuit operations of the semiconductor chip. Especially, it is assumed that the stress concentration occurs around the UBM film under the bump electrode. The stress is applied to a passivation film of the semiconductor chip. The passivation film tends to crack, and may serve as a route of entry of liquid which may soak through wirings or a route of entry of contaminants which may degrade properties of a transistor. This would lead to lowered reliability of the semiconductor device.

Japanese Patent Laid-Open Publication No. Hei 7-58114 describes a semiconductor device, in which a bump electrode is smaller than a UBM film (barrier metal film) in order to reduce stress concentration caused around the UBM film. This semiconductor device is fabricated as described hereinafter. First of all, a resist mask having an opening to downsize the bump electrode is formed on the UBM film using the photolithographic technique. The UBM film is exposed via the opening on the resist mask. The UBM film includes a film which is incompatible to solder, and is either a nitride film or an oxide film. Solder is applied on the UBM film at an area surrounded by the solder-incompatible film. The solder is used as the bump electrode. The UBM film is patterned using the solder and solder-incompatible film as an etching mask.

The following problems seem to remain unsolved with the semiconductor device of the above-cited publication. After making the solderincompatible film, the resist mask is formed by the photolithographic technique, and is used to pattern the UBM film. As is well known, the photolithographic technique requires a number of steps such as application, exposure, development and cleaning of the resist. Therefore, the making of the solder-incompatible film inevitably increases a number of fabrication steps for the semiconductor device.

### BRIEF SUMMARY OF THE INVENTION

According to the embodiment of the invention, there is provided a method of manufacturing a semiconductor device. The method includes making an opening on a passivation film extending over an external terminal on a substrate, the opening communicating with the external terminal; making a first under bump metal film (a first UBM film) on the passivation film, the first under bump metal film being in contact with the external terminal via the opening and having no wettability to a bump electrode; making a second under bump metal film (a second UBM film) on the first under bump metal film, the second under bump metal film having the wettability to the bump electrode; placing the bump electrode on the second under bump metal film on the external terminal; patterning the second under bump metal film using the bump electrode as a mask, and side -etching the second under bump metal film until a peripheral edge of the second umber bump metal film reaches a lower peripheral edge of the bump electrode; filling a resist in a space defined by the side-etched part of the second under bump metal film; and patterning the first under bump metal film using the bump electrode and the resist as a mask.

### BRIEF DESCRIPTION OF THE INVENTION

FIG. 1 is a cross section of an essential part of a semiconductor device to be fabricated according to an embodiment of the invention;

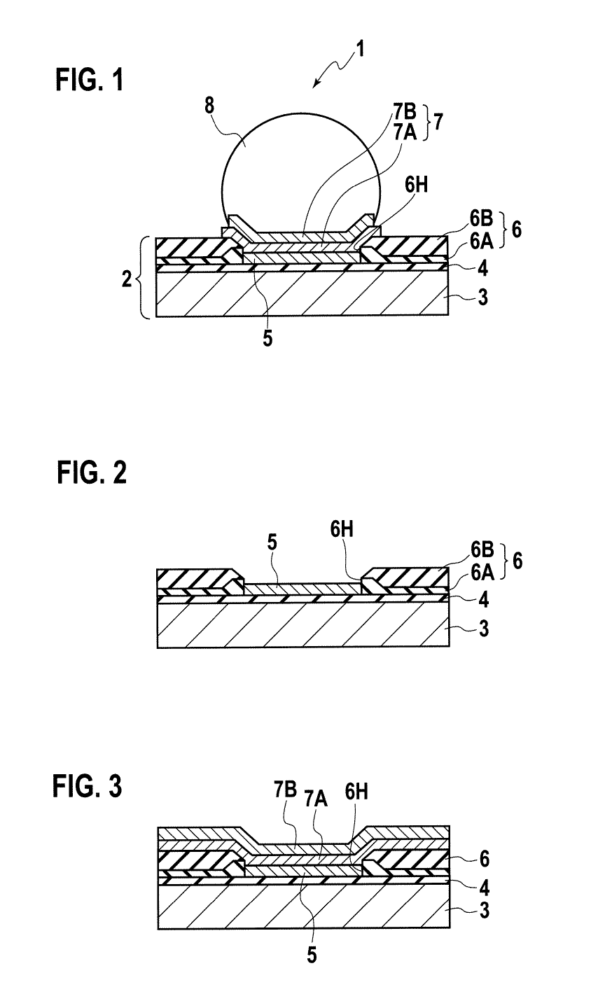

FIG. 2 is a cross section showing how the semiconductor device is fabricated in a first step;

FIG. 3 is a cross section showing how the semiconductor device is fabricated in a second step;

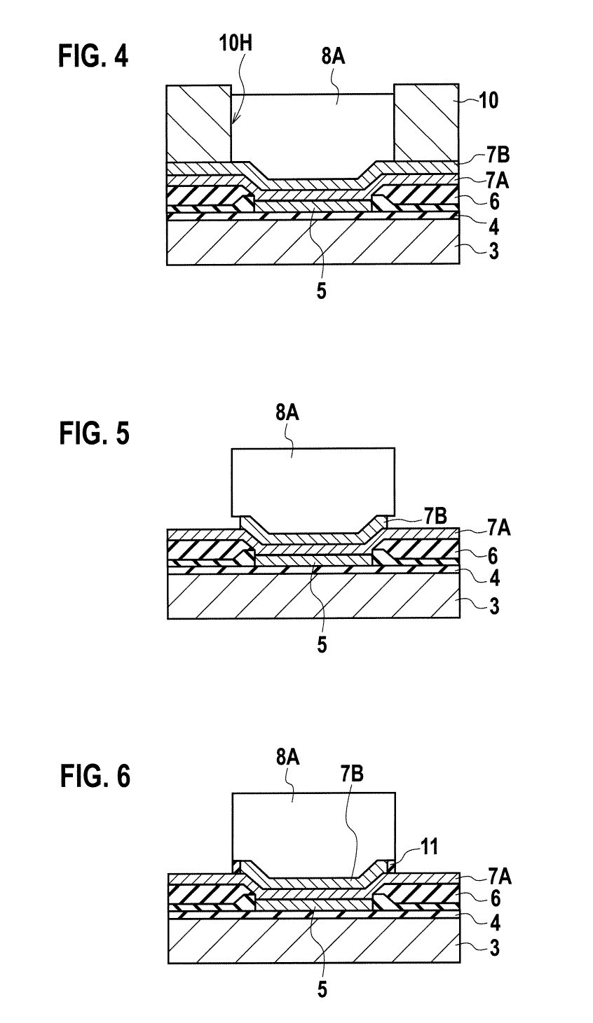

FIG. 4 is a cross section showing how the semiconductor device is fabricated in a third step;

FIG. 5 is a cross section showing how the semiconductor device is fabricated in a fourth step;

FIG. 6 is a cross section showing how the semiconductor device is fabricated in a fifth step;

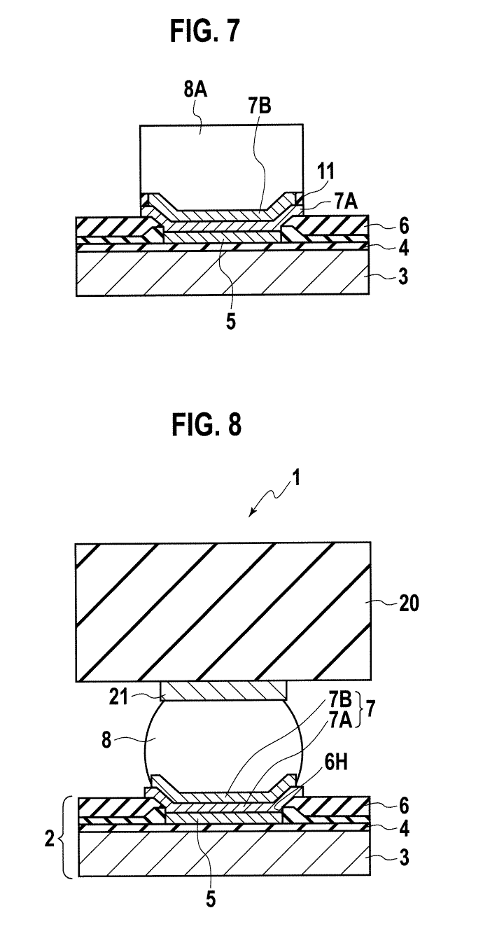

FIG. 7 is a cross section showing how the semiconductor device is fabricated in a sixth step; and

FIG. 8 is a cross section showing how the semiconductor device is fabricated in a seventh step.

### DETAILED DESCRIPTION OF THE INVENTION

The invention will be described hereinafter with reference to one embodiment shown in the drawings. The invention is assumed to be applied to manufacturing a semiconductor device in which a bump electrode is formed on an external terminal on a semiconductor chip (substrate) via a UBM film.

(Configuration of Semiconductor Device)

Referring to FIG. 1, a semiconductor device 1 includes a semiconductor chip 2, which is used as one of substrates to be joined by the flip-chip method. The other substrate (not shown) is similar to the semiconductor chip 2, and is a wiring substrate (e.g. PCB: printed-circuit board), an insulating substrate, a glass substrate, or the like.

The semiconductor chip 2 is mainly constituted by a silicon single crystal substrate 3, on which a transistor, a resistor and a capacitor, element connecting wirings and so on are mounted, and functions as an integrated circuit (not shown). In FIG. 1, a plurality of wiring layers and insulating layers placed between the wiring layers are simply depicted as a foundation 4.

An external terminal (bonding pad) 5 is placed on the silicon single crystal substrate 3 via the foundation 4. Although not shown, the external terminal 5 is electrically connected to the integrated circuit via one of wirings. The external terminal 5 is mainly made of an aluminum alloy film to which a minute amount of silicon and/or copper is added, for instance, and is flush with the wiring of the final wiring layer. Specifically, the external terminal 5 is constituted by either a single aluminum alloy film or a composite film of a barrier metal film, an aluminum alloy film, and an antireflection film which are sequentially stuck.

A passivation film (final protective film) 6 is placed on the silicon single crystal substrate 3 as well as the external terminal 5. The passivation film 6 includes a silicon oxide film 6A which has a fine texture and is prepared by the plasma CVD process, and a silicon oxide film 6B which is prepared by the CVD process, is contains boron or phosphor, and is placed on the silicon oxide film 6A. The silicon oxide film 6B is a PSG film or BPSG film. The external terminal 5 has an opening 6H made by removing a part of the passivation film 6. The opening 6H is smaller than the external terminal 5 considering an alignment allowance in the fabrication process.

Above the external terminal 5, a UBM film 7 is placed over a part of the periphery of the opening 6H of the passivation film 6. The UBM film 7 is a foundation for a bump electrode 8, is electrically conductive, has high adhesive properties to the external terminal 5, and has wettability to the bump electrode 8. In this embodiment, the UBM film 7 includes a first UBM film 7A and a second UBM film 7B. The first UBM film 7A has high adhesive properties to the external terminal 5, and does not have the wettability to the bump electrode 8. The second UBM film 7B is placed on the first UBM film 7A, and has the wettability to the bump electrode 8. The UBM film 7 usually includes the first and second UBM films 7A and 7B. Alternatively, the UBM film 7 may also include an intermediate UBM film between the UBM films 7A and 7B, thereby improving adhesive properties between them, and lowering thermal expansion coefficients. The UBM film 7 may include three or more films.

The first UBM film 7A is preferably a metal film such as a titanium (Ti) film, a chromium (Cr) film, a tungsten (W) film, a titanium-tungsten (TiW) film, a cobalt (Co) film and a beryllium (Be), or an alloy film, and is prepared by the sputtering process. The first UBM film 7A is approximately 100 nm to 1000 nm thick. The second UBM film 7B is preferably a metal film such as a copper (Cu) film, a nickel (Ni) film, an iron (Fe) film, a gold (Au) film, a palladium (Pd) film, or an alloy film containing the foregoing materials, and is prepared by the sputtering process. The second UBM film 7B is approximately 100 nm to 1000 nm thick.

The bump electrode 8 is preferably made of lead-tin (Pb—Sn) solder. Alternatively, the bump electrode 8 may be a binary system alloy or a ternary compound system alloy, or lead-free solder.

(Method of Manufacturing Semiconductor Device)

The semiconductor device 1 will be fabricated through the steps shown in FIG. 2 to FIG. 8. First of all, the silicon single crystal substrate 3 is prepared as shown in FIG. 2. The silicon single crystal substrate 3 has on its main surface an integrated circuit, wirings connecting elements of the integrated circuit, passivation film 6, and opening 6H on the external 5 of the passivation film 6. In other words, the silicon single crystal substrate 3 is in the state of a silicon wafer to which most of preparations prior to the dicing process has been completed in the semiconductor manufacturing process. After the dicing process, the silicon single crystal substrate 3 is segmented, and becomes the semiconductor chip 2.

The first UBM film 7A is deposited all over the passivation film 6 (on the silicon single crystal substrate 3) via the opening 6H. The first UBM film 7A is in contact with the external terminal 5. Refer to FIG. 3. The first UBM film 7A is the Ti film which has no wettability to the bump electrode 8 and is prepared by the sputtering process, as described above.

Referring to FIG. 3, the second UBM film 7B is deposited all over the first UBM film 7A. The second UBM film 7B is the Cu film which has the wettability to the bump electrode 8 and is prepared by the sputtering process, as mentioned previously. In this state, the UBM film 7 having the two UBM films 7A and 7B is completed.

The resist mask 10 having an opening 10H over the external terminal 5 is formed all over the UBM film 7 (refer to FIG. 4). The resist mask 10 is a photoresist mask prepared by the photolithographic process, for instance.

As shown in FIG. 4, the resist mask 10 is used to selectively form a bump electrode 8A on the second UBM film 7B in the opening 10H. For this purpose, the soldering process is applied, for instance. In this state, the bump electrode 8A is not yet subject to the reflow treatment.

The resist mask 10 is removed by the photolithographic process. The second UMB film 7B is etched and patterned using the bump electrode 8A as an etching mask, as shown in FIG. 5. In this case, the UBM film 7B under the bump electrode 8A is left as it is. The second UBM film 7B is side-etched until it reaches the peripheral edge of the bump electrode 8A, specifically until it recedes from a lower peripheral edge of the bump electrode 8A. The bump electrode 8A and the first UBM film 7A (which is exposed after the second UBM film 7B has been removed) are used as an etching mask. In between the under surface of the bump electrode 8A and the upper surface of the first UBM film 7A, the second UBM film 7B is backed by the side-etching. The second UBM film 7B is preferably patterned using the isotropic etching such as the wet etching.

Referring to FIG. 6, a resist 11 is filled only in a space defined by the lower peripheral edge of the bump electrode 8A, side-etched part of the second UBM film 7B, and the exposed surface of the first UBM film 7A. The resist 11 is filled as follows. A liquid resist is spin-coated into the foregoing space using the photolithographic process, and is then hardened. A surplus part of the hardened resist material is uniformly removed so that the resist 11 remains only in the foregoing space. The resist 11 is reliably self-aligned to the bump electrode 8A without any misalignment on fabrication process. A thickness of the resist 11 depends upon a side-etched extent of the second UBM film 7B.

The first UBM film 7A is patterned using the bump electrode 8A and the resist 11 as an etching mask as shown in FIG. 7. The patterning of the first UBM film 7A is preferably subject to the anisotropic etching such as the dry etching. The second UBM film 7B is smaller by the thickness of the resist 11 than the patterned first UBM film 7A. In this state, the UBM film 7 including the UBM films 7A and 7B is completed. Further, the second and first UBM films 7B and 7A are self-aligned to the bump electrode 8A because the resist 11 is self-aligned to the bump electrode 8A. Thereafter, the resist 11 will be selectively removed.

When the UBM film 7 including the first UBM film 7A and the second UBM film 7B which is smaller than the first UBM film 7A is made, it is not necessary to form a film incompatible to solder and to perform the patterning process using the photolithography. Therefore, the number of semiconductor manufacturing processes can be extensively reduced.

The bump electrode 8A is reflowed, fused and coagulated, so that it is ensphered and is changed to the spherical bump electrode 8 as shown in FIG. 1. In this state, the semiconductor chip 2 having the spherical bump electrode 8 on the external terminal 5 via the UBM film 7 is completed.

As shown in FIG. 8, the spherical bump electrode 8 is brought into contact with an external terminal 21 of a wiring substrate 20, and is reflowed, so that the external terminal 5 of the semiconductor chip 2 is electrically connected to and is mechanically joined to the external terminal 21 of the wiring substrate 20. Thus, the semiconductor device 1 according to the invention is completed.

As described above, the second UBM film 7B is smaller than the first UBM film 7A. The spherical bump electrode 8 is downsized in accordance with the size of the second UBM film 7B. This is effective in reducing the stress concentration at the periphery of the first UBM film 7A, and in extensively reducing the number of semiconductor manufacturing steps.

### Other Embodiments

The present invention is not limited to the embodiment, and may be modified in a variety of ways without departing from the spirit of the invention. The invention has been described to be applied to the semiconductor device in which the semiconductor chip 2 and the wiring substrate 20 are connected via the bump electrode 8. Alternatively, the invention may be applied to a semiconductor device in which semiconductor chips 2 or wiring substrates 20 may be connected.

As described, the invention provides the method of manufacturing the semiconductor device. In the method, the bump electrode is made smaller than the UMB film, and steps for lowering the stress concentration around the UMB film are reduced, which is effective in reducing the number of the semiconductor manufacturing steps.

What is claimed is:

1. A method of manufacturing a semiconductor device, the method comprising:
making an opening on a passivation film extending over an external terminal on a substrate, the opening communicating with the external terminal;
making a first under bump metal film on the passivation film, the first under bump metal film being in contact with the external terminal via the opening and having no wettability to a bump electrode;
making a second under bump metal film on the first under bump metal film, the second under bump metal film having the wettability to the bump electrode;
placing the bump electrode on the second under bump metal film on the external terminal;
patterning the second under bump metal film using the bump electrode as a mask, and side-etching the second under bump metal film until a peripheral edge of the second umber bump metal film reaches a lower peripheral edge of the bump electrode;
filling a resist in a space defined by the side-etched part of the second under bump metal film; and
patterning the first under bump metal film using the bump electrode and the resist as a mask.

2. The method defined in claim 1, wherein the first under bump metal film is a metal film like a titanium film, a chromium film, a tungsten film, a titanium-tungsten film, a cobalt film, or a beryllium film.

3. The method defined in claim 1, wherein the first under bump metal film is an alloy film of titanium, chromium, tungsten, titanium-tungsten, cobalt, or beryllium.

4. The method defined in claim 1, wherein the first under bump metal film is 100 nm to 1000 nm thick.

5. The method defined in claim 1, wherein the second umber bump metal film is a metal film like a copper film, a nickel film, an iron film, a gold film or a palladium film.

6. The method defined in claim 1, wherein the second under bump metal film is an alloy film of copper, nickel, iron, gold or palladium.

7. The method defined in claim 1, wherein the second under bump metal film is 100 nm to 1000 nm thick.

8. The method defined in claim 1, wherein the bump electrode is made of tin-lead solder.

9. The method defined in claim 1, wherein the bump electrode is made of a binary system alloy or a ternary compound system alloy.

10. The method defined in claim 1, wherein the bump electrode is made of lead-free solder.

11. The method defined in claim 1, wherein the bump electrode is prepared by a plating process.

12. The method defined in claim 1, further comprising reflowing the patterned first under bump metal film and making the bump electrode spherical.

13. The method defined in claim 1, wherein the resist is filled only under the peripheral edge of the bump electrode while the bump electrode is self-aligned.

14. The method defined in claim 12, wherein the resist is filled only under the peripheral edge of the bump electrode while the bump electrode is self-aligned.

15. The method defined in claim 13, wherein the first under bump metal film is patterned while the bump electrode is self-aligned.

16. The method defined in claim 14, wherein the first under bump metal film is patterned while the bump electrode is self-aligned.

17. The method defined in claim 1, wherein the substrate is a semiconductor chip, a wiring substrate, an insulating substrate, or a glass substrate.

18. The method defined in claim 1, further comprising connecting a wiring substrate to the bump electrode.
